(19) United States
(12) Patent Application Publication
(10) Pub. No.: US 2015/0077930 A1
(43) Pub. Date: Mar. 19, 2015

(54) DATA PROCESSING RACK UNIT

(71) Applicant: FUJITSU LIMITED, Kawasaki-shi (JP)

(72) Inventors: Yoshimi KADOTANI, Kawasaki (JP); Takashi SAITOU, Kawasaki (JP)

(21) Appl. No.: 14/551,357

(22) Filed: Nov. 24, 2014

Related U.S. Application Data
(63) Continuation of application No. PCT/JP2012/064119, filed on May 31, 2012.

(51) Int. Cl. H05K 7/20

(52) U.S. Cl. CPC H05K 7/20781
USPC 361/679.53

(57) ABSTRACT

A data processing rack unit including: a rack; a data processing device; a cable; a coupling member that is connected to a water pipe that is formed at a column positioned on the one side out of a plurality of columns and through which cooling water flows, and that extends toward one side; a cooling water pipe that is provided at the data processing device and cools an internal portion of the data processing device; and a coupled-to member that is provided at a location on the one side of the data processing device, that is connected to the cooling water pipe, that extends toward the opposite side from the one side, and that is coupled to the coupling member accompanying insertion of the data processing device into the rack.

### CROSS-REFERENCE TO RELATED APPLICATION

This application is a continuation application of International Application No. PCT/JP/2012/064119, filed May 31, 2012, the disclosure of which is incorporated herein by reference in its entirety.

### FIELD

Technology disclosed herein relates to a data processing rack unit.

### BACKGROUND

Known data processing rack units include a rack with plural columns, and with data processing devices that are mounted by insertion into the rack from a front face side of the rack. Such data processing rack units include a data processing rack unit in which a water pipe, through which cooling water flows, is formed at a column positioned at a back face side out of the plural columns of the rack. Cooling water supplied through the water pipe cools an internal portion of the data processing device.

### RELATED PATENT DOCUMENTS

Japanese Laid-Open Patent Publication No. 2002-374086

### SUMMARY

According to an aspect of the embodiments, a data processing rack unit includes: a rack including plural columns; a data processing device that is mounted by insertion into the rack from one side in a horizontal direction; a cable leading out from the data processing device to an opposite side from the one side; a coupling member that is connected to a water pipe that is formed at a column positioned on the one side out of the plurality of columns and through which cooling water flows, and that extends toward the one side; a cooling water pipe that is provided at the data processing device and cools an internal portion of the data processing device; and a coupled-to member that is provided at a location on the one side of the data processing device, that is connected to the cooling water pipe, that extends toward the opposite side from the one side, and that is coupled to the coupling member accompanying insertion of the data processing device into the rack.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a perspective view illustrating a data processing rack unit.

FIG. 2 is a horizontal cross-section illustrating a data processing rack unit.

FIG. 3 is an enlarged perspective view illustrating relevant portions of a data processing rack unit.

FIG. 4 is an enlarged perspective view illustrating relevant portions of a data processing rack unit.

FIG. 5 is an enlarged horizontal cross-section illustrating relevant portions of a data processing rack unit.

FIG. 6 is an explanatory drawing to explain how a coupling member and a coupled-to member couple together.

FIG. 7 is an explanatory drawing to explain how a coupled state of a coupling member and a coupled-to member is released.

FIG. 8 is an explanatory drawing to explain a cooling water circulation system in a data processing rack unit and cooling water supply device.

### DESCRIPTION OF EMBODIMENTS

Explanation follows regarding an exemplary embodiment of technology disclosed herein.

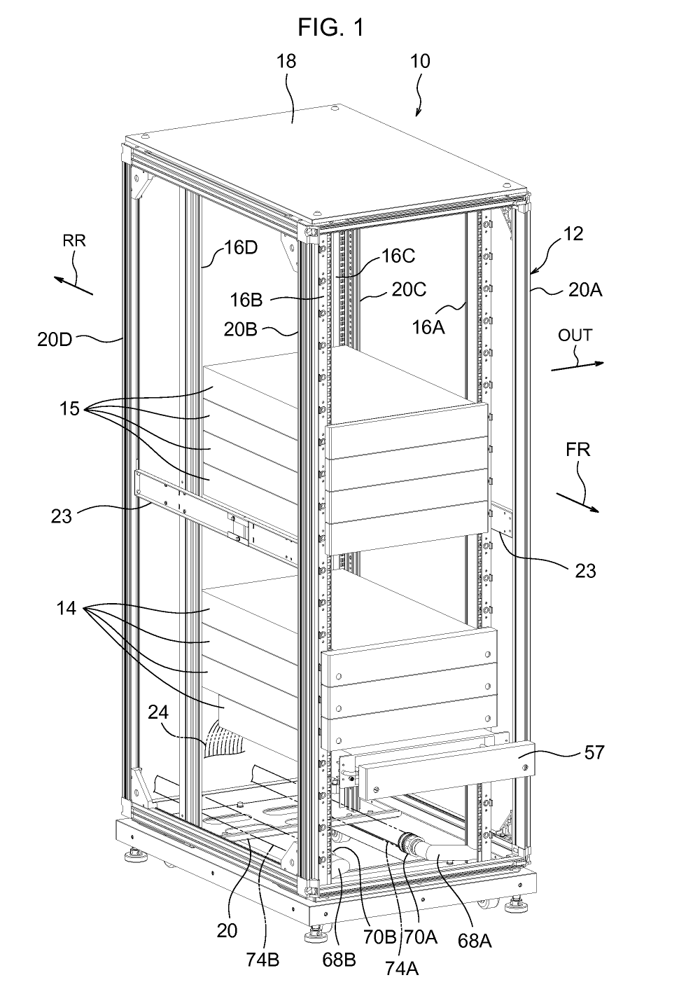

As illustrated in FIG. 1, a data processing rack unit 10 according to the present exemplary embodiment includes a rack 12, plural data processing devices 14, and plural data processing devices 15.

The rack 12 includes plural columns 16A to 16D, a top panel 18, and a bottom frame 20. The plural columns 16A to 16D are disposed at positions corresponding to four corner portions of the data processing devices 14, 15. The top panel 18 is formed in a rectangular shape in plan view, and has a larger external profile than the data processing devices 14, 15.

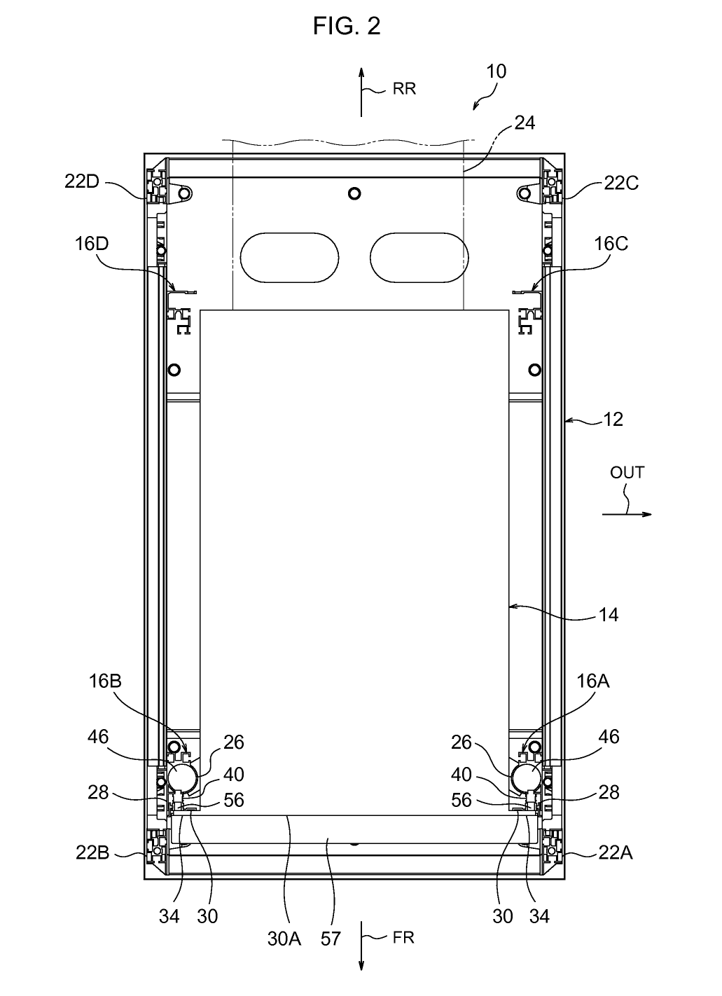

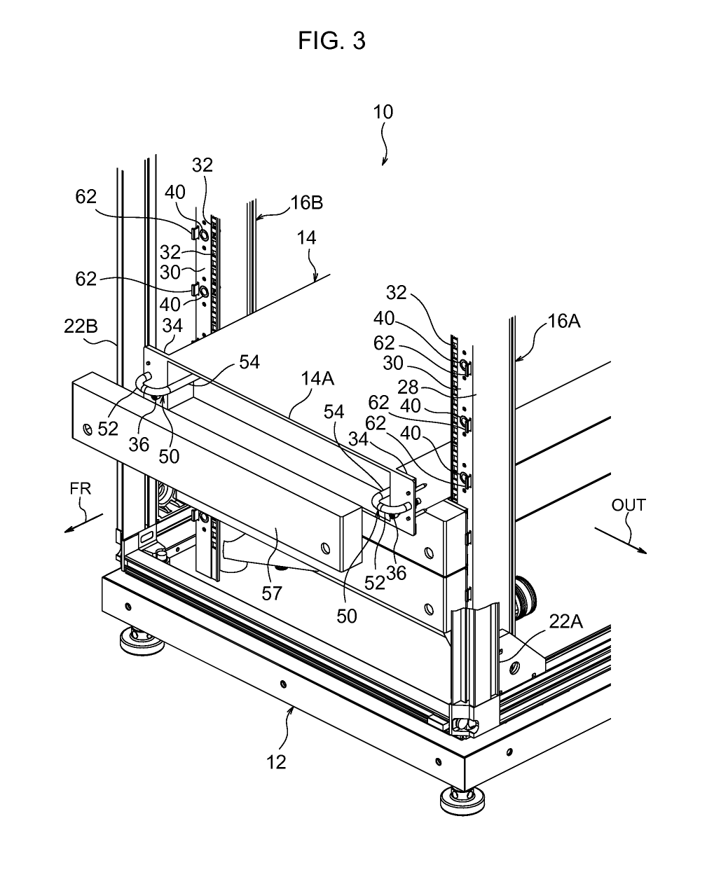

The rack 12 is provided with plural outer columns 22A to 22D at the outside of the plural columns 16A to 16D (see also FIG. 2 and FIG. 3). The plural outer columns 22A to 22D are disposed at positions corresponding to the four corner portions of the top panel 18. The plural outer columns 22A to 22D and the plural columns 16A to 16D are respectively joined to the top panel 18 and the bottom frame 20. The outer column 22A and the outer column 22C, and the outer column 22B and the outer column 22D, are also respectively coupled together by side frames 23 extending along the front-rear direction of the rack 12.

The plural data processing devices 14 illustrated in FIG. 1 have substantially the same external profile as each other. The plural data processing devices 14 are stacked in the height direction of the rack 12. Each of the data processing devices 14 is mounted into the rack 12 by insertion from a front face side (arrow FR side) of the rack 12. Cables 24 lead out from back faces of each of the data processing devices 14 to a back face side (arrow RR side) of the rack 12. The plural data processing devices 14 are connected to an external device through the cables 24. The front face side of the rack 12 is an example of one side in a horizontal direction, and the back face side of the rack 12 is an example of an opposite side from the one side described above.

Note that, as described later, the plural data processing devices 14 are water-cooled, and the plural data processing devices 15 are air-cooled.

As illustrated in FIG. 2, out of the plural columns 16A to 16D, the columns 16A, 16B positioned on the front face side of the rack 12 are respectively formed with water pipes 26, through which cooling water flows. The water pipes 26 are formed with circular cross-section profiles, and extend in the height direction of the rack 12, forming main body portions of the columns 16A, 16B. The overall columns 16A, 16B, including the water pipes 26, are formed by extrusion molding, and have a uniform cross-section along the length direction. The columns 16A, 16B are respectively disposed sideways of the data processing devices 14.

The rack 12 and the data processing devices 14 are formed with substantially left-right symmetry as viewed from the front. Accordingly, in the present exemplary embodiment, explanation is chiefly given regarding configuration of the right hand side half, with explanation regarding configuration of the left hand side half omitted.

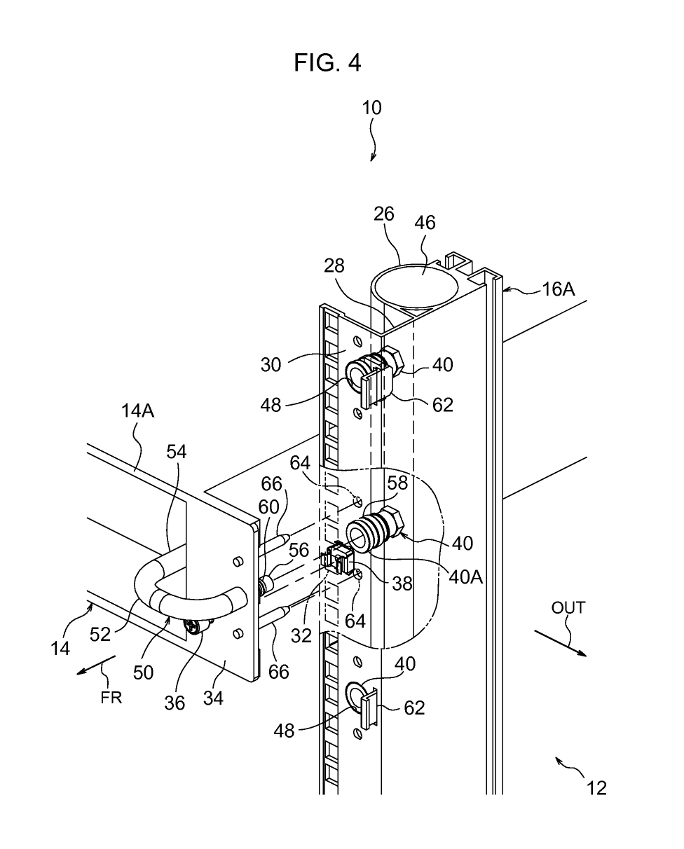

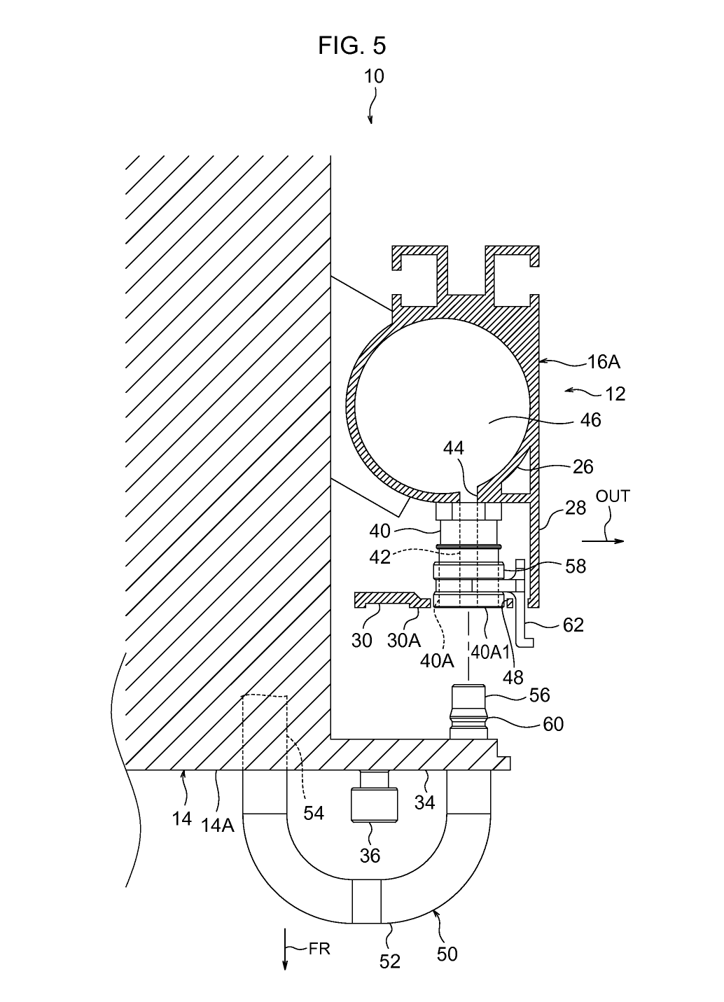

As illustrated in FIG. 4, the column 16A including the water pipe 26 is formed with an extension portion 28 and a bent portion 30. As illustrated in FIG. 5, the extension portion 28 extends from a location of the column 16A on the opposite side to the side of the data processing devices 14 (the column 16A outside, the arrow OUT side) toward the front face side of the rack 12. The bent portion 30 bends around from a leading end portion of the extension portion 28 towards a side of the data processing devices 14 (the rack 12 inside, the opposite side to the arrow OUT side). As illustrated in FIG. 4, a leading end portion of the bent portion 30 is formed with plural mounting holes 32 in a row at intervals in the height direction of the rack 12. Each of the mounting holes 32 is formed in a rectangular shape as viewed from the front.

A location on the rack 12 front face side of each of the data processing devices 14 is formed with a flange 34 that projects out sideways of the data processing device 14 (the arrow OUT side), and faces the bent portion 30. An attachment screw 36 is provided passing through the flange 34. A cage nut 38 is attached to a given mounting hole 32 out of the plural mounting holes 32, and the flange 34 is fixed to the bent portion 30 by screwing the attachment screw 36 into the cage nut 38. The placement of each of the data processing devices 14 in the height direction of the rack 12 is adjusted by selectively attaching the cage nuts 38 to given mounting holes 32 out of the plural mounting holes 32.

As illustrated in FIG. 4 and FIG. 5, coupling members 40 are connected to the water pipe 26. Each coupling member 40 extends toward the front face side of the rack 12. As illustrated in FIG. 5, the coupling member 40 includes a through path 42 passing through along the axial direction. The through path 42 is in communication with a water path 46 inside the water pipe 26 through a connection hole 44 formed in an outer wall portion of the water pipe 26. The bent portion 30 is formed with through holes 48 at positions corresponding to the coupling members 40, with leading end portions 40A of the coupling members 40 housed inside the respective through holes 48. An end face 40A1 of the leading end portion 40A of each coupling member 40 is formed in the same plane as a front face 30A of the bent portion 30.

Each of the data processing devices 14 is provided with cooling water pipes 50 for cooling the inside of the data processing device 14. The cooling water pipes 50 are preferably made from copper, which has high thermal conductivity, however they may also be made from resin. Each cooling water pipe 50 is formed with a U-shaped portion 52 that is bent around into a U-shape.

The U-shaped portion 52 is disposed further to the front face side of the rack 12 than the data processing device 14 (flange 34), and is exposed to the outside of the data processing device 14. One end of the U-shaped portion 52 is connected to a cooling portion 54 of the cooling water pipe 50, housed inside the data processing device 14. The other end of the U-shaped portion 52 is connected to a coupled-to member 56. The U-shaped portion 52, the flange 34, and a front face 14A of the data processing device 14 are covered by a front cover 57 (see FIG. 3) from the front face side of the rack 12.

The coupled-to member 56 is provided at the flange 34 as an example of a location on the rack 12 front face side of the data processing device 14. The coupled-to member 56 extends toward the opposite side to the rack 12 front face side, and is coupled to the coupling member 40 accompanying insertion of the data processing device 14 into the rack 12. More specifically, the coupled-to member 56 is coupled to the coupling member 40 in an inserted state inside the coupling member 40. The coupled-to member 56 and the cooling water pipe 50 are formed with a flow path, not illustrated in the drawings, that is in communication with the water path 46 through the through path 42 described above.

A ring shaped fixing member 58 (sleeve) is mounted to a leading end outer peripheral portion of the coupling member 40. The fixing member 58 is disposed between the water pipe 26 and the bent portion 30, and is capable of movement along the axial direction of the coupling member 40. The fixing member 58 is biased toward the rack 12 front face side by a resilient member such as a spring, not illustrated in the drawings. A ridge shaped engagement portion 60 is formed around the circumferential direction of an outer peripheral portion of the coupled-to member 56.

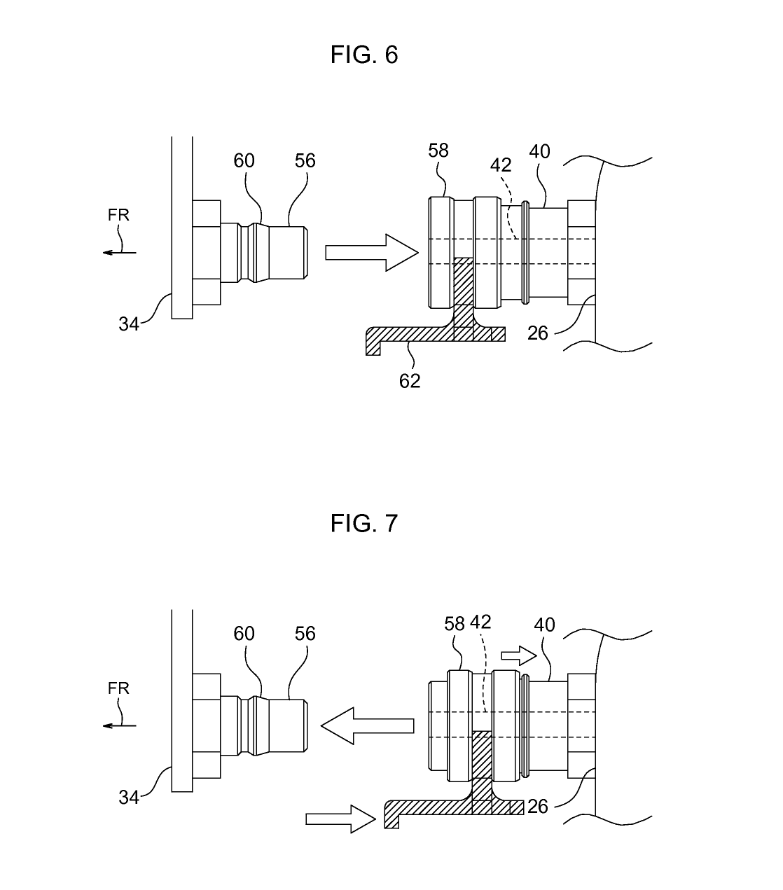

As illustrated in FIG. 6, the fixing member 58 and the engagement portion 60 engage with each other in a state in which the fixing member 58 is positioned toward the front face side (arrow FR side) of the rack 12, thereby fixing together the coupling member 40 and the coupled-to member 56. Moreover, as illustrated in FIG. 7, the engaged state of the fixing member 58 and the engagement portion 60, and the fixed state of the coupling member 40 and the coupled-to member 56, are released in a state in which the fixing member 58 is positioned toward the opposite side to the front face side of the rack 12. Note that the coupling member 40 is provided with a check valve mechanism, not illustrated in the drawings, and the through path 42 is closed off by the check valve mechanism in a state in which the coupling member 40 is not coupled to the coupled-to member 56.

The fixing member 58 is further provided with an ejector 62 that extends toward the front face side of the rack 12. As illustrated in FIG. 5, the ejector 62 passes through the bent portion 30 and projects out toward further toward the front face side of the rack 12 than the bent portion 30. The ejector 62 is disposed alongside the coupling member 40 in a lateral width direction of the rack 12. Pushing the ejector 62 toward the opposite side to the front face side of the rack 12 moves the fixing member 58, releasing the engagement between the fixing member 58 and the engagement portion 60.

Moreover, as illustrated in FIG. 4, the bent portion 30 is formed with guide holes 64. The guide holes 64 pass through the bent portion 30 in the plate thickness direction. The flange 34 is moreover provided with guide pins 66 extending toward the opposite side to the front face side of the rack 12. The guide holes 64 are an example of a guide portion, and the guide pins 66 are an example of a guided portion. The guide holes 64 and the guide pins 66 are provided at both the upper side and lower side of the coupling member 40 and the coupled-to member 56 respectively. A pair of the guide pins 66 are inserted into the respective guide holes 64 and guided by the guide holes 64 accompanying insertion of the data processing device 14 into the rack 12.

As illustrated in FIG. 1, a pair of connection pipes 68A, 68B are provided at a lower portion of the rack 12. One of the connection pipes 68A is connected to a lower portion of the one water pipe 26 of the column 16A illustrated in FIG. 2, and the other of the connection pipes 68B is connected to a lower portion of the other water pipe 26 of the column 16B illustrated in FIG. 2. Welding, for example, is employed for the connection between the pair of connection pipes 68A, 68B and the respective water pipes 26. Moreover, as illustrated in FIG. 1, a leading end portion of the one connection pipe 68A configures a water inlet 70A, and a leading end portion of the other connection pipe 68B configures a water outlet 70B.

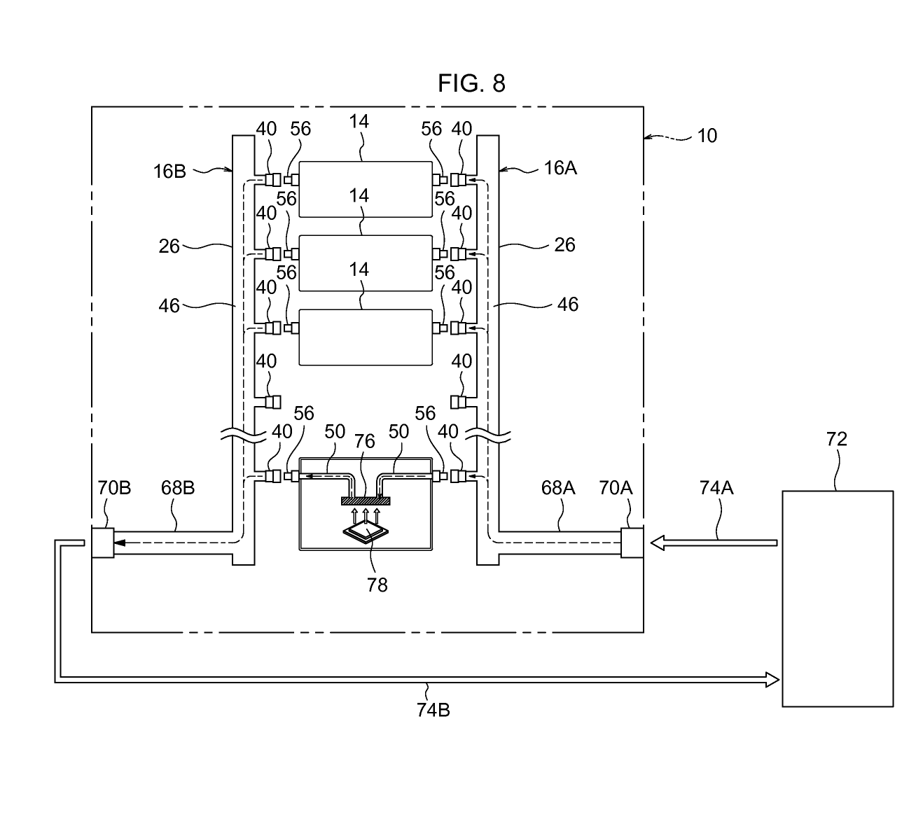

The pair of connection pipes 68A, 68B extend out toward the back face side (arrow RR side) of the rack 12 and are connected through members including the connection hoses 74A, 74B to a cooling water supply device 72 (see FIG. 8) that supplies cooling water. The pair of connection pipes 68A, 68B are disposed below the data processing device 14 that is bottommost out of the plural data processing devices 14. Note that the connection hoses 74A, 74B connected to the connection pipes 68A, 68B may lead out to the outside of the rack 12 from the back face of the rack 12, or may lead out to the outside of the rack 12 from a bottom face of the rack 12.

When cooling water is conveyed from the cooling water supply device 72 illustrated in FIG. 8, the cooling water is supplied to one cooling water pipe 50 through the one connection pipe 68A, the water pipe 26 of the one column 16A, and the coupling member 40 and coupled-to member 56 connected to the water pipe 26. Supplying the cooling water to the cooling water pipe 50 supplies cooling water to a cooling board 76 provided inside the data processing device 14, thereby cooling a heat generating member 78 that is disposed in close proximity to the cooling board 76.

The cooling water that has passed through the inside of the data processing device 14 is returned to the cooling water supply device 72 through the coupled-to member 56 and coupling member 40 connected to the other cooling water pipe 50, the water pipe 26 of the other column 16B, and the other connection pipe 68B. The above operation is performed non-stop, cooling the heat generating member 78 continuously.

Explanation follows regarding operation and advantageous effects of the present exemplary embodiment.

As described in detail above, the rack 12 includes the water pipes 26 through which cooling water flows, as illustrated in FIG. 2. The water pipes 26 are formed at the columns 16A, 16B positioned on the front face side of the rack 12 (on the opposite side to the side provided with the cables 24) out of the plural columns 16A to 16D. Placement space for the water pipes 26, the coupling members 40, and the coupled-to members 56 can accordingly be simply secured, since it is possible to prevent the water pipes 26, the coupling members 40 and the coupled-to members 56 from interfering with the cables 24. A reduction in size of the rack 12 can accordingly be achieved.

Moreover, as illustrated in FIG. 4 and FIG. 5, the coupling member 40 extends from the water pipe 26 toward the front face side (arrow FR side) of the rack 12, and the coupled-to member 56 extends from the location on the rack 12 front face side of the data processing device 14 toward the opposite side to the front face side of the rack 12. The coupling member 40 and the coupled-to member 56 are coupled together accompanying insertion of the data processing device 14 into the rack 12. Accordingly, the coupling member 40 and the coupled-to member 56 have a simple coupling operation, since it is sufficient to insert the data processing device 14 into the rack 12 in order to couple together the coupling member 40 and the coupled-to member 56. The data processing rack unit 10 can accordingly be made user-friendly (for example, in terms of ease of operation when performing maintenance or adding data processing devices 14).

The location on the rack 12 front face side of the data processing device 14 is formed with the respective flanges 34 that project out sideways of the data processing device 14 and are fixed to the columns 16A, 16B. The coupled-to members 56 are provided at the flanges 34. A member to support the coupled-to members 56 is thereby rendered unnecessary, enabling the structure to be simplified.

The flanges 34 face the bent portions 30 and are fixed to the bent portions 30. The flanges 34 can accordingly be easily fixed to the bent portions 30.

As illustrated in FIG. 5, the bent portions 30 are formed with the through holes 48 at positions corresponding to the coupling members 40. The leading end portions 40A of the coupling members 40 are housed inside the through holes 48. The leading end portions 40A of the coupling members 40 can thus be protected by peripheral edge portions of the through holes 48.

As illustrated in FIG. 4, the bent portions 30 are formed with the guide holes 64, and the flanges 34 are provided with the guide pins 66 that extend toward the opposite side to the front face side of the rack 12. When inserting the data processing device 14 into the rack 12, the guide pins 66 are guided by the guide holes 64 accompanying this insertion. Guiding the guide pins 66 with the guide holes 64 enables positioning of the coupling members 40 and the coupled-to members 56 to be performed, thereby enabling coupling of the coupling members 40 and the coupled-to members 56 to be facilitated.

Specifically, the guide holes 64 and the guide pins 66 are respectively provided at both the upper side and lower side of the coupling member 40 and the coupled-to member 56. This enables more precise positioning of the coupling members 40 and the coupled-to members 56, thereby enabling coupling of the coupling members 40 and the coupled-to members 56 to be made even easier.

The coupling member 40 is provided with the fixing member 58 that fixes and releases the fixing between the coupling member 40 and the coupled-to member 56. The ejector 62 extends from the fixing member 58 toward the front face side of the rack 12. Pushing the ejector 62 in toward the opposite side to the front face side of the rack 12 moves the fixing member 58 and releases the engagement between the fixing member 58 and the engagement portion 60. Since a pulling out direction of the coupled-to member 56 from the coupling member 40 (the arrow FR direction) is set as the opposite direction to the pushing in direction of the ejector 62, good ease of operation can be achieved when pulling the coupled-to member 56 out after pushing the ejector 62 in.

Moreover, the ejector 62 is disposed alongside the coupling member 40 in the lateral width direction of the rack 12. Good ease of operation can accordingly be achieved for the ejector 62 when pulling the coupled-to member 56 out from the coupling member 40 (when pulling the flange 34 away from the bent portion 30).

The fixing member 58 is disposed between the water pipe 26 and the bent portion 30. Since the fixing member 58 can be protected by the water pipe 26 and the bent portion 30, unintentional movement of the fixing member 58 to a fixing release position (a position toward the opposite side to the front face side of the rack 12) can be suppressed. The ejector 62 moreover passes through the bent portion 30, and projects out further toward the front face side of the rack 12 than the bent portion 30. Good ease of operation can accordingly be secured for the ejector 62.

As illustrated in FIG. 2, the respective water pipes 26 form the main body portions of the columns 16A, 16B, such that the rigidity of the respective columns 16A, 16B can be increased by the water pipes 26.

The columns 16A, 16B are respectively formed with the extension portion 28 that extends toward the front face side of the rack 12, and the bent portion 30 that is bent round from the leading end portion of the extension portion 28, as well as the water pipe 26. The rigidity of the respective columns 16A, 16B can accordingly be further increased, since the extension portion 28 and the bent portion 30 form an L-shape in plan view.

The connection pipes 68A, 68B that are connected to the cooling water supply device 72 (see FIG. 8) extend out toward the back face side of the rack 12 as illustrated in FIG. 1. The connection hoses 74A, 74B connected to the connection pipes 68A, 68B can accordingly be prevented from interfering with the water pipes 26, the coupling members 40, and the coupled-to members 56.

The connection pipes 68A, 68B are disposed below the bottommost of the plural data processing devices 14, namely in a dead space of the rack 12. The dead space of the rack 12 can accordingly be effectively used, enabling a reduction in size of the rack 12 (in particular, the height of the rack 12 can be suppressed).

The overall columns 16A, 16B are formed by extrusion molding, enabling a reduction in manufacturing costs of the columns 16A, 16B.

Explanation follows regarding modified examples of the present exemplary embodiment.

In the present exemplary embodiment, the data processing devices 14 are mounted by insertion into the rack 12 from the front face side of the rack 12, however the data processing devices 14 may be mounted by insertion into the rack 12 from another side, as an example of one side in the horizontal direction.

The guide holes 64 and the guide pins 66 are employed as an example of a guide portion and a guided portion, however other structures may also be employed.

The columns 16A, 16B include the extension portion 28 and the bent portion 30 as well as the water pipe 26, however the columns 16A, 16B may be formed with another cross-section profile.

As illustrated in FIG. 5, the extension portion 28 extends toward the front face side of the rack 12 from a location on the opposite side of the column 16A to the side of the data processing devices 14 (the outside of the column 16A, the arrow OUT side). However, the extension portion 28 may extend toward the front face side of the rack 12 from a location on the data processing device 14 side of the column 16A (the inside of the column 16A, the opposite side to the arrow OUT side). In such a configuration, the bent portion 30 may bend around from the leading end portion of the extension portion 28 toward the opposite side to the data processing device 14 side (the outside of the rack 12, the arrow OUT side).

One aspect of technology disclosed herein has been described above, however the technology disclosed in the present application is not limited to the above, and it goes without saying that various modifications may be implemented within a range not departing from the spirit of the technology disclosed herein.

The technology disclosed herein enables a reduction in the size of a rack, and enables improved user-friendliness in a data processing rack unit.

All cited documents, patent applications and technical standards mentioned in the present specification are incorporated by reference in the present specification to the same extent as if the individual cited documents, patent applications and technical standards were specifically and individually incorporated by reference in the present specification.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A data processing rack unit comprising:
a rack including a plurality of columns;
a data processing device that is mounted by insertion into the rack from one side in a horizontal direction;
a cable leading out from the data processing device to an opposite side from the one side;
a coupling member that is connected to a water pipe that is formed at a column positioned on the one side out of the plurality of columns and through which cooling water flows, and that extends toward the one side;
a cooling water pipe that is provided at the data processing device and cools an internal portion of the data processing device; and
a coupled-to member that is provided at a location on the one side of the data processing device, that is connected to the cooling water pipe, that extends toward the opposite side from the one side, and that is coupled to the coupling member accompanying insertion of the data processing device into the rack.

2. The data processing rack unit of claim 1, wherein:
the column including the water pipe is disposed sideways of the data processing device, and the location on the one side of the data processing device is formed with a flange that projects out sideways of the data processing device and is fixed to the column including the water pipe; and
the coupled-to member is provided at the flange.

3. The data processing rack unit of claim 2, wherein:
the column including the water pipe is formed with an extension portion extending toward the one side, and a bent portion bending around from a leading end portion of the extension portion; and
the flange faces the bent portion and is fixed to the bent portion.

4. The data processing rack unit of claim 3, wherein:
the bent portion is formed with a through hole at a position corresponding to the coupling member; and
a leading end portion of the coupling member is housed inside the through hole.

5. The data processing rack unit of claim 2, wherein:
the column including the water pipe is provided with a guide portion; and
the flange is provided with a guided portion that is guided by the guide portion accompanying insertion of the data processing device into the rack.

6. The data processing rack unit of claim 5, wherein:
the guide portion is a guide hole; and
the guided portion is a guide pin that extends toward the opposite side from the one side and is inserted into the guide hole.

7. The data processing rack unit of claim 6, wherein:
the guide holes and the guide pins are respectively provided at both an upper side and a lower side of the coupling member and the coupled-to member.

8. The data processing rack unit of claim 1, further comprising:
a fixing member that is provided at the coupling member, that fixes together the coupling member and the coupled-to member in a state in which the fixing member is positioned toward the one side, and that releases the fixed state between the coupling member and the coupled-to member in a state in which the fixing member is positioned toward the opposite side from the one side; and
an ejector that extends from the fixing member toward the one side.

9. The data processing rack unit of claim 8, wherein:
the ejector is disposed alongside the coupling member.

10. The data processing rack unit of claim 8, wherein:
the column including the water pipe is formed with an extension portion extending toward the one side, and a bent portion bending around from a leading end portion of the extension portion;
the fixing member is disposed between the water pipe and the bent portion; and
the ejector passes through the bent portion and projects out further toward the one side than the bent portion.

11. The data processing rack unit of claim 1, wherein:
a connection pipe connected to a cooling water supply device that supplies cooling water is provided at a lower portion of the water pipe; and
the connection pipe extends toward the opposite side from the one side.

12. The data processing rack unit of claim 11, further comprising:
a plurality of the data processing devices, wherein the plurality of the data processing devices are stacked in the height direction of the rack; and
the connection pipe is disposed below a data processing device that is bottommost out of the plurality of the data processing devices.

13. The data processing rack unit of claim 1, wherein:
the column including the water pipe is formed by extrusion molding.

14. The data processing rack unit of claim 13, wherein:
the water pipe forms a main body portion of the column
